(19) United States
(12) Patent Application Publication
(10) Pub. No.: US 2025/0164547 A1
(43) Pub. Date: May 22, 2025

(54) Defect Monitor

(71) Applicant: Taiwan Semiconductor Manufacturing Company, Ltd., Hsinchu (TW)

(72) Inventors: Mei-Chen Chuang, Hsinchu (TW); Shenggao Li, Hsinchu (TW); Hamza Al-Maharmeh, Hsinchu (TW)

(21) Appl. No.: 18/517,078

(22) Filed: Nov. 22, 2023

(51) Int. Cl. G01R 31/28

(52) U.S. Cl. CPC G01R 31/2853

(57) ABSTRACT

Circuits, methods, and devices are provided. A circuit for detecting degradation of a via comprises a current source configured to deliver a constant current supply to a plurality of conductive vias of a device under testing. The circuit further includes a plurality of switches configured to connect the current source to the plurality of vias, and an analog-to-digital converter (ADC) configured to be connected to the plurality of vias by the plurality of switches through a first wire that is connected to a first input of the ADC. The plurality of switches are configured to connect one via of the plurality of vias at a time to the current source and to the first wire, and the ADC is configured to output a signal that represents the resistance of a via connected to the ADC and the current source.

### BACKGROUND

The ongoing trend of miniaturization in the semiconductor industry has led to smaller, faster devices with improved power consumption. A key development for this trend has been the development of features, such as the through-silicon-via (TSV), which is a conductive interconnect that extends vertically though a substrate enabling stacked packaging of semiconductor devices. Modern semiconductor packages can include thousands of these beneficial features, such as TSVs interconnecting components across multiple levels.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1 is a diagram depicting a circuit for measuring the resistance of a via, according to an embodiment.

FIGS. 2A and 2B are a diagram depicting a circuit for measuring the resistance of a plurality of vias and a graph of an output signal of the circuit according to an embodiment.

FIGS. 3A and 3B are schematic diagrams depicting semiconductor devices including a plurality of vias in embodiments.

FIG. 4 is a diagram depicting a circuit for measuring the resistance of a plurality of vias within a semiconductor device according to an embodiment.

FIG. 5 is a diagram depicting a circuit for measuring the resistance of a plurality of vias in accordance with embodiments.

FIG. 6 is a diagram depicting a circuit for measuring the resistance of a plurality of vias according to another embodiment.

FIG. 7 is a diagram depicting a circuit for measuring the resistance of a plurality of vias according to another embodiment.

FIGS. 8A, 8B, and 8C are diagrams depicting example measurements from a circuit for measuring the resistance of a plurality of vias according to an embodiment.

FIG. 9 is a flowchart depicting a method of testing a semiconductor device according to an embodiment.

Corresponding numerals and symbols in the different figures generally refer to corresponding parts unless otherwise indicated. The figures are drawn to clearly illustrate the relevant aspects of the embodiments and are not necessarily drawn to scale.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in some various examples. This repetition is for the purpose of simplicity and clarity and does not in itself dictate a relationship between some various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Some embodiments of the disclosure are described. Additional operations can be provided before, during, and/or after the stages described in these embodiments. Some of the stages that are described can be replaced or eliminated for different embodiments. Additional features can be added to the circuit. Some of the features described below can be replaced or eliminated for different embodiments. Although some embodiments are discussed with operations performed in a particular order, these operations may be performed in another logical order.

As described above, features such as TSVs are becoming more and more prevalent in semiconductor devices. Over time, one or more TSVs within a package may degrade causing an undesired increase in resistance through the via. Although this may increase the resistance of an individual TSV substantially, in modern devices including hundreds, or even thousands, of TSVs it is difficult to detect and locate the degraded via. Some modern devices may also incorporate super power rails (SPRs), another form of via that can be smaller than traditional TSVs while providing backside power delivery to a device. Detecting and locating degraded SPRs presents similar challenges to those for TSVs.

For example, the resistance through a TSV or SPR may be on a scale of tenths of an Ohm and a capacitance on each end of the via may be on a scale of femtofarads (10⁻¹⁵). Accordingly, the RC characteristics of an individual via are generally so small that it is difficult to detect an outlier. By placing all of the TSVs in a package in series and plotting the measured resistance, a statistical model may be used to detect degraded TSVs generally. But such a test may not be precise enough to pick up such small variations in resistance. Alternatively, degraded vias can be detected by measuring a delay caused by each via in a package; however at the small scales of modern devices, even if resistance through a degraded via becomes 10,000 times larger, the delay difference may only be around 10 picoseconds, which may be difficult to detect.

To overcome these issues, embodiments described herein may use four-wire sensing (e.g., Kelvin sensing) to measure the resistance across each TSV of a device or package. Four-wire sensing is a technique for accurately measuring the resistance of a component that uses two pairs of wires (four wires total). The first pair of wires supplies current through the component and the second pair of wires measures the voltage across the component. The resistance can then be determined from the input current and the measured voltage. Four-wire sensing aims to eliminate the resistance of the wires in the circuit, leading to more precise measurements of low resistance values.

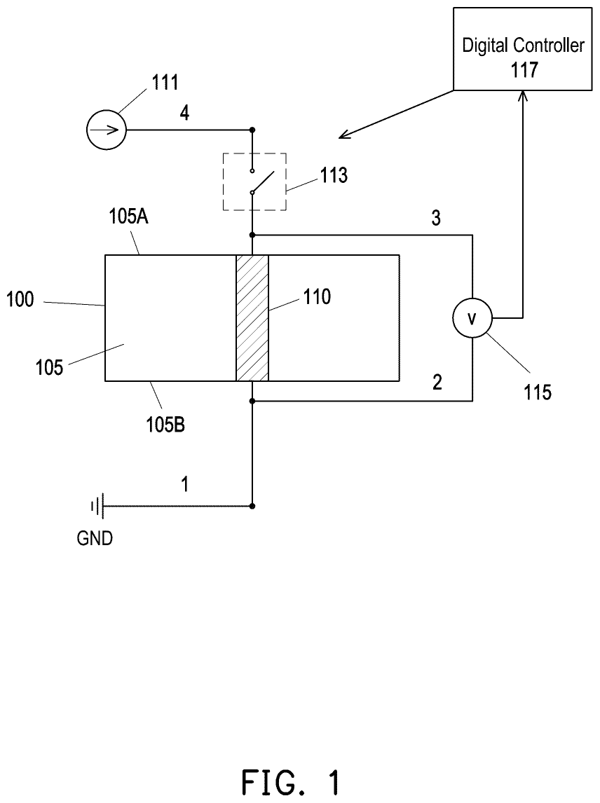

For example, FIG. 1 is a diagram depicting a circuit for measuring the resistance across a via according to an embodiment. FIG. 1 shows only a measurement across a single via 110, but embodiments described herein may be capable of evaluating hundreds or thousands of vias or more in a package or device. In an embodiment, a circuit for measuring resistance across a via may receive a device under testing (DUT) 100. The device under testing may comprise a substrate 105 and a via 110 configured to carry signals between components below the substrate and components above the substrate. Via 110 may extend from a bottom surface of the substrate 105B to a top surface of the substrate 105A. The via 110 may comprise a TSV or a SPR as described above. The substrate 105 may also comprise interconnects and metallization layers (not shown) that connect the via 110 to components on or in the substrate 105.

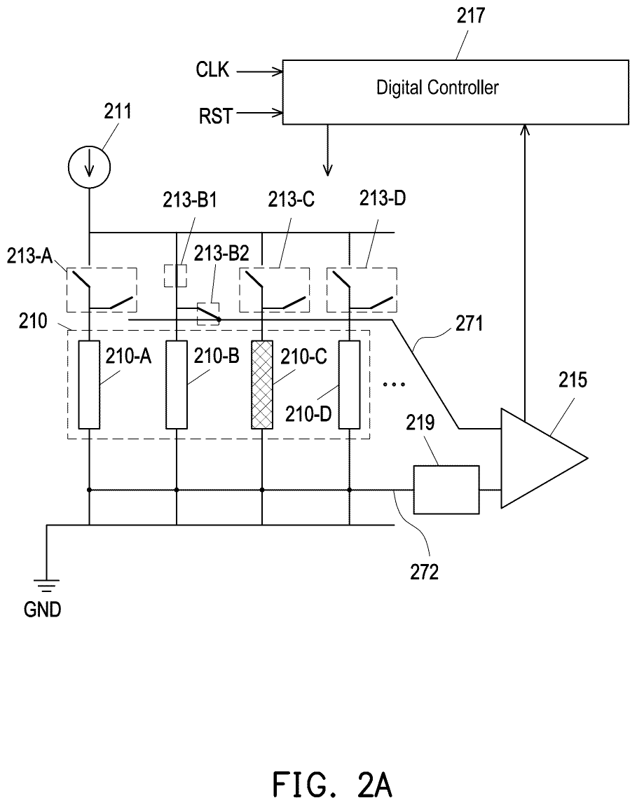

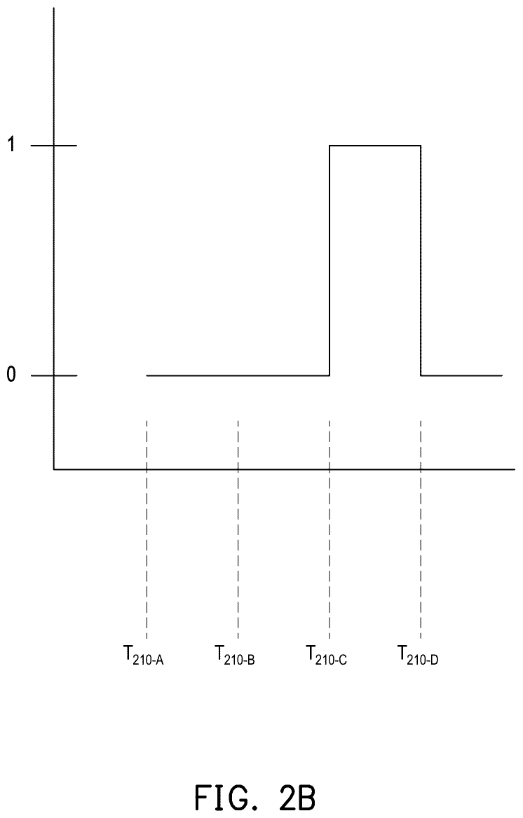

To measure the resistance of the via 110 a four-wire sensing method may be employed. To do so, the circuit may comprise four wires, labeled 1-4 in FIG. 1, which may be connected to an electrical path from one side of the via 110 to the other. The circuit may further comprise a current source 111, a switch 113, a voltage measuring device 115, and a digital controller 117. The digital controller 117 may control the switch 113. When the switch is closed, via 110 is connected to current source 111 and sensing may occur. As described in greater detail below with respect to FIG. 2, switch 113 and digital controller 117 may allow one via at a time to be connected to the current source 1111, thereby enabling the measurement process to determine which via is generating an output signal at a given time.

When switch 113 is closed, outside wires 1 and 4 may form a current path that carries a known current through the via 110 supplied by the current source 111. Inside wires 2 and 3 each connect to the current path adjacent to and on opposites sides of the via 110. Wires 2 and 3 create a sensing path comprising the voltage measuring device 115, which measures a voltage drop across the via 110. The voltage measuring device 115 may send signals reporting the measured data to the digital controller 117. Using Ohm's law, the resistance of the via 110 can be calculated from the measured voltage and the known current.

In an embodiment, the voltage measuring device 115 may be an analog-to-digital converter (ADC). An ADC is an electronic component that takes a continuous analog signal as an input and outputs a discrete digital signal. For example, an ADC acting as the voltage measuring device 115 may monitor the voltage across the TSV as an input signal, and output digital representations of that signal over time.

The output signal may be a binary signal that outputs a “1” (high) or “0” (low) based on the measured voltage. The ADC may be configured to switch from low to high, or high to low, at a particular input threshold voltage. This threshold voltage may set such that it corresponds with a resistance through the via 110 that indicates a degraded via. Accordingly, the circuit can measure whether the via 110 is degraded based on whether the ADC outputs a high signal or a low signal. In embodiments comprising multiple vias, the ADC may be connected to each via of the package, and the digital controller may toggle switches on and off in a specific order, thereby connecting the different vias to the ADC one at a time. In this type of circuit, the output of the ADC represents a voltage measurement for each via in the sequence. By monitoring the output of the ADC, the presence and location of a degraded via can be determined. Such a circuit is described in more detail below with respect to FIGS. 2A and 2B.

FIG. 2A is a diagram depicting a circuit for measuring the resistance of a plurality of vias 210 according to an embodiment. The circuit of FIG. 2A can measure the resistance of many vias within a device or package, and may provide a means for determining the location of any degraded vias. For example, the plurality of vias 210 may be a part of a device that is connected to the circuit in order to undergo testing. In an embodiment, the plurality of vias 210 may comprise vias 210-A, 210-B, 210-C, and 210-D. The vias may comprise TSVs and/or SPRs, as described above. While only four vias are shown in the figure, it will be appreciated that hundreds, or even thousands of vias may be connected to the circuit.

In a similar manner to that described above with respect to FIG. 1, the plurality of vias 210 may be connected to four-wire sensing arrangement in order to measure the voltage drop across individual vias, thereby providing a measurement of the resistance of each via. In an embodiment, the circuit may further comprise a current source 211, an ADC 215 serving as a voltage measuring device, and a digital controller 217. The digital controller may control a plurality of switches that are arranged in correspondence with the plurality of vias 210A-D.

To complete the four-wire sensing arrangement, the vias 210-A-D may be connected to the ADC 215 on both a top and bottom side of each via. On the top side, each via may be connected to a conductive wire 271 that connects to a first input of the ADC 215. This connection may be enacted by switches that are controlled by the digital controller 217. The manner in which these switches are turned on and off is described in greater detail below. On the bottom side, each via may be connected to a second conductive wire 272 that connects to second input of the ADC 215. In an embodiment, the ADC 215 may be located in a device and routing layer on a top side of the plurality of vias. Accordingly, in order for wire 272 to connect to the second input of the ADC 215, it must be routed back through the substrate through return vias 219. Return vias 219 may comprise one or a plurality of vias configured specifically to make this connection.

The plurality of switches may comprise first switches 213-A, second switches 213-B1 and 213-B2, third switches 213-C, and fourth switches 213-D. Further switches may be provided in the same manner as shown for each via that is connected to the circuit and subject to measurement and testing. Each via is connected to a set of two switches, one of which connects the via to the current source 211 and another of which connects the via to conductive wire 271, which further connects to a first input of the ADC 215. FIG. 2 shows switches 213-A, 213-C, and 213-D in an off position wherein corresponding vias 210-A, 210-C, and 210-D are not connected to the ADC 215. Switches 213-B1 and 213-B2, however, are in an on position thereby connecting via 210-B to the ADC 215 to enable a measurement of the voltage across, and consequently the resistance of, the via.

The switches 213-A-D may be controlled by digital controller 217, which opens and closes the switches so as to connect and disconnect vias 210-A-D to ADC 215. Digital controller 217 may do this in a pre-determined order. Because the output of the ADC 215 measures the resistance across each via, by connecting the vias in a particular order, the output of the ADC can indicate exactly which vias in an array of hundreds or thousands of vias are degraded.

For example, in testing the reliability of a number of vias in a package or chip, the digital controller 217 may first use switches 213-A to connect via 210-A to ADC 215 while the other switches are open. The ADC may then output a first reading corresponding to the voltage across, and consequently the resistance through via 210-A. Next, digital controller 217 may disconnect via 210-A from the ADC 215 and may close switches 213-B1 and 213-B2 so as to connect via 210-B to the ADC 215 resulting in a second reading corresponding to the voltage across, and consequently the resistance through via 210-B. Thereafter, digital controller 217 may disconnect via 210-B from the ADC 215 and use switches 213-C connect via 210-C to the ADC, resulting a third reading corresponding to the voltage and resistance associated with via 210-C. The digital controller may then disconnect via 210-D and use switches 213-D to connect via 210-D to the ADC 215, resulting in a fourth reading corresponding to the voltage and resistance associated with via 210-D. While only four pairs of vias and switches are shown, this process can be continued for any number of cycles in order to obtain a reading for every via in a package.

In the example described above, via 210-C may represent a degraded via. As such, the output of the ADC 215 may be different when measuring across via 210-C as compared to those of normally functioning vias 210-A, 210-B, and 210-D. FIG. 2B depicts a graph showing an example output of the ADC 215 according to an embodiment. The graph plots the ADC signal output vs. time. The signal may vary between 0 and 1 depending on the voltage and resistance of the via being measured. The dashed vertical lines in the figure show the timing of the measurement of each of 210-A, 210-B, 210-C, and 210-D.

In an embodiment, the ADC may be tuned to have a threshold voltage that is set at a level to indicate that a via being measured is degraded. This voltage may vary based on the design and the level of sensitivity needed. According to Ohm's law (V=IR), at a constant supply current, when the resistance of a measured via is within a normal operating range, the measured voltage will also be in a normal operating range. This voltage may be below the threshold voltage of the ADC and result in an “0” output signal. FIG. 2B shows that measurements of 210-A (at a time T_{210-A}) and 210-B (at a time T_{210-B}) result in such an output signal. When a measurement occurs across degraded via 210-C, the measured voltage is above the threshold voltage of the ADC resulting a “1” output signal at time T_{210-C}. When the measurement proceeds to 210-D, the output signal returns to “0” at time T_{210-D}. In such a configuration, any degraded vias will result in a “1” output. Thus, the output signal can be compared against the pre-determined order in which the vias are connected to the ADC to determine the location of any degraded vias.

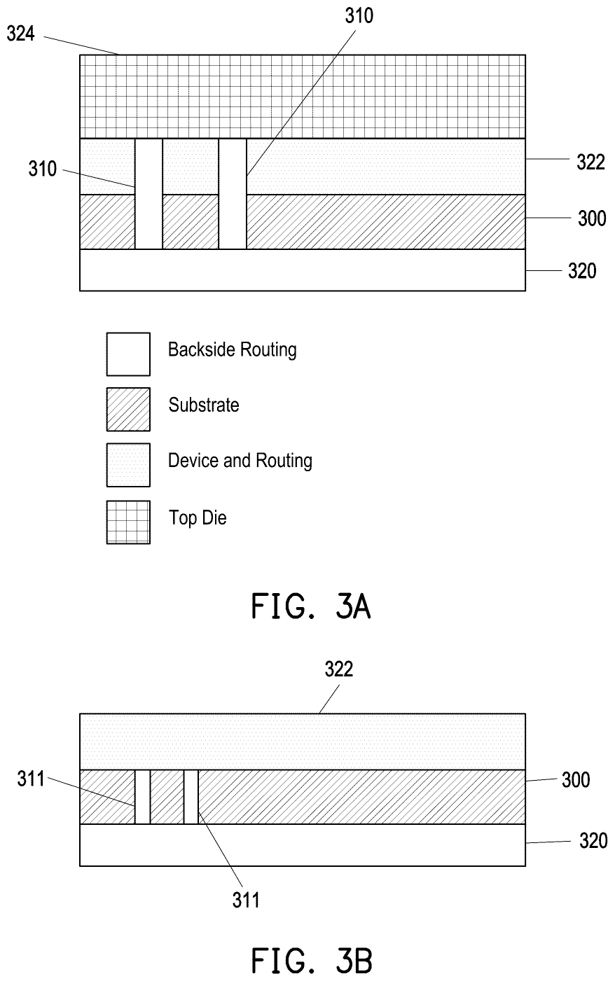

FIGS. 3A and 3B are schematic diagrams depicting semiconductor devices including a plurality of vias. The devices depicted in FIGS. 3A and 3B may be connected to a circuit as described above in order to measure the resistance across the plurality of vias of the device. In an embodiment, a device may be a device under testing (DUT) connected to a circuit for detecting via degradation so as to form a testing system.

The device of FIG. 3A may comprise a plurality of TSVs 310. TSVs 310 may provide connection through a substrate 300 and a device and routing layer 322 to pads or other interconnects of a top die 324. Components of a measurement circuit such as a current source or ADC may also be located in the device and routing layer 322, such the device can be easily connected to the circuit as a DUT for detection of any degradation of the vias 310. As described above, this may require the measurement circuit to include return vias that connect a bottom of the plurality of TSVs 310 back through the substrate 300 to the routing layer 322.

The device of FIG. 3B may comprise a plurality of SPRs 311. The SPRs 311 may have a smaller diameter than the TSVs of FIG. 3A. In an embodiment, SPRs may be formed through a substrate 300 to connect between backside routing 320 and a device and routing layer 322. The SPRs may terminate at a top surface of the substrate and not extend further into device and routing layer 322. Similar to the device described in FIG. 3A, a device including a plurality of SPRs may be connected to a circuit for measuring the resistance of the plurality of SPRs. Components of this circuit may be disposed within the device and routing layer 322 and backside routing layer 320. In some embodiments, the device may comprise a combination of TSVs 310 and SPRs 311.

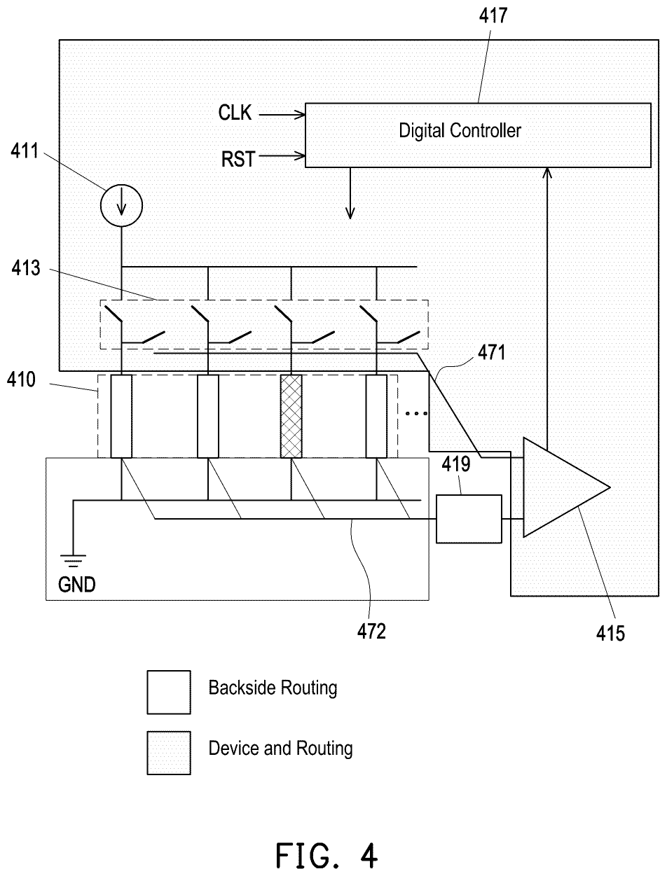

FIG. 4 is a diagram depicting a circuit for measuring the resistance of a plurality of vias within a semiconductor device according to an embodiment. The circuit depicted in FIG. 4 may be used to measure the plurality of vias of a semiconductor device like those described above with respect to FIGS. 3A and 3B. Accordingly, the location of some components within the device is shown in FIG. 4 (for example showing that some components are located in a device and routing layer, while the bottom side wires are located in a backside routing layer).

The components of the circuit in FIG. 4 may be similar to those described above with respect to FIG. 2A. For example, a plurality of vias 410 may be connected to a four-wire sensing scheme using a plurality of switches 413. The plurality of switches 413 may connect and disconnect the plurality of vias 410 of a device under testing to a current source 411 and an ADC 415 through a first wire 472. The other side of the plurality of vias 410 may be connected to another input of the ADC 415 through a second wire 472 and return vias 419.

A digital controller 417 may control the plurality of switches 413, as well as receive output signals from the ADC 415. In an embodiment, components on the top side of the plurality of vias may be located in a device and routing layer, while components on a bottom side of the plurality of vias may be located in a backside routing layer. By connecting the vias 410 to the current source 411 and ADC 415 in this manner, accurate measurements of the voltage across and resistance through each via can be made, allowing detection of the precise location of any degraded vias.

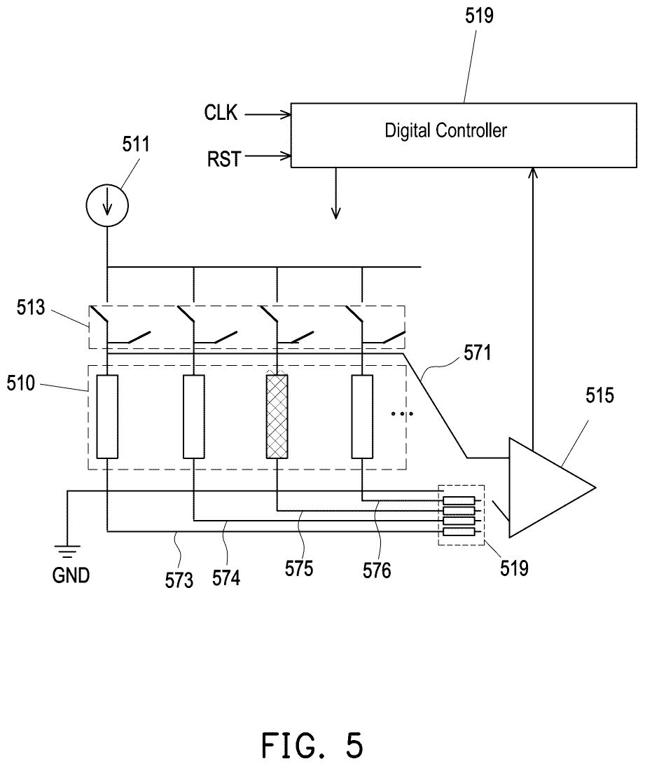

FIG. 5 is a diagram depicting a circuit for measuring the resistance of a plurality of vias according to an embodiment. The components of the circuit may be similar to those described above with respect to FIG. 2A and FIG. 4. For example, a plurality of vias 510 may be connected to a four-wire sensing scheme in order to determine the voltage across, and resistance through, each via. This scheme may comprise a plurality of switches 513 controlled by a digital controller 517 to connect and disconnect the plurality of vias 510 to and from a current source 511 and an ADC 515. On a top side of the vias, the switches connect each via to the ADC 515 through a first wire 571.

In this example, the bottom of each via of the plurality of vias 510 is connected to an individual wire located in the backside routing layer. A first via may be connected to a second wire 573, a second via may be connected to a third wire 574, a third via may be connected to a fourth wire 575, and a fourth via may be connected to a fifth wire 576. This plurality of wires may connect to a second input of the ADC 515 through return vias 519. In this way, the wires on the bottom side of the plurality of vias 510 may be provided in a one-to-one correspondence with the plurality of vias. Additionally, there may be a one-to-one correspondence between the vias making up return vias 519, the plurality of vias 510, and plurality of wires on the bottom side of the plurality of vias. The second input of the ADC 515 may be connected to a switch, also controlled by digital controller 517, to connect to a corresponding return via of the return vias 519. In such an embodiment, each via is also associated with an individual return via. Connecting the vias in this way may decrease the risk of circuit failure when a return via degrades. Rather than a degraded return via causing issues for multiple measurements, this type of connection scheme may ensure that a degraded return via affects the measurement of only one via to be measured.

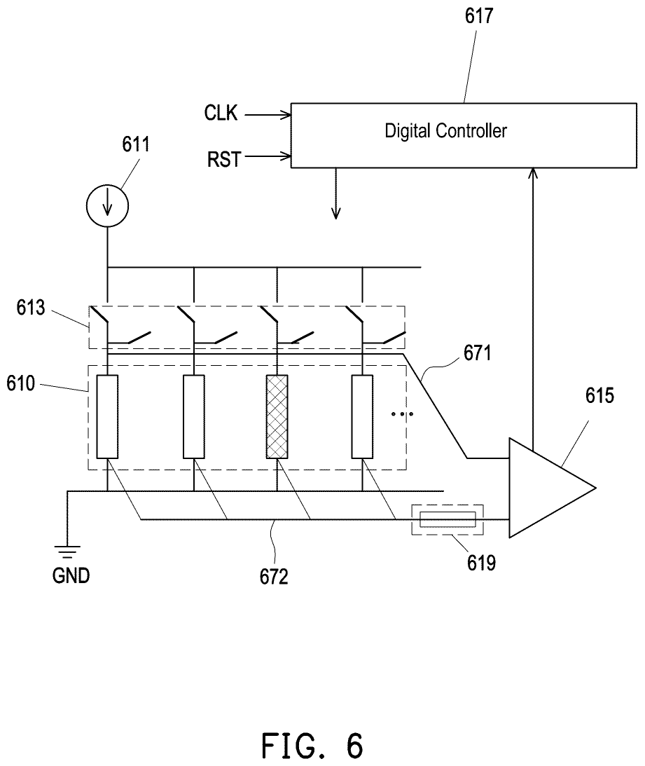

FIG. 6 is a diagram depicting a circuit for measuring the resistance of a plurality of vias according to another embodiment. Components in FIG. 6 may be similar to those in examples described above. For example a plurality of vias 610 may be connected to a four-wire sensing scheme in order to determine the voltage across and resistance through each via. This scheme may comprise a plurality of switches 613 controlled by a digital controller 617 to connect and disconnect the plurality of vias 610 to and from a current source 611 and an ADC 615. On a top side of the vias, the switches may connect each via to a first input of ADC 615 through a first wire 671.

In this example, each via of the plurality of vias 610 may connect to a single second wire 672. The resistance of second wire 672 may be greater than a resistance of the path between the plurality of vias and a ground voltage GND. The second wire 672 may provide a connection between the bottom side of the plurality of vias and a second input of the ADC 615. This connection may pass through return vias 619. The return vias may comprise two TSVs that share the signal routing between the bottom side of the plurality of vias and the second input of the ADC 615. By providing two vias connected to the second wire 672 to complete this backside routing, failure of the circuit due to a single return TSV degrading may be avoided. This configuration may also take up less space and include a greater number of devices under testing (DUT) in a given area.

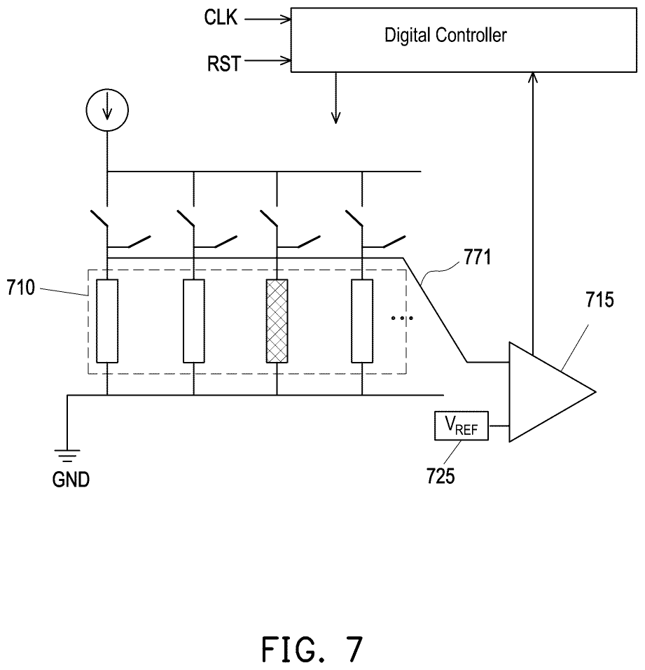

FIG. 7 is a diagram depicting a circuit for measuring the resistance of a plurality of vias according to another embodiment. Components in FIG. 7 may be similar to those in examples described above, but rather than connecting the bottom side of each via of the plurality of vias 710 to a second input of the ADC 715, the second input of the ADC may be connected to a reference voltage V_{REF} 725. In an embodiment, ADC 715 may be a comparator having a first input connected to a first wire 771 that connects to the top side of the plurality of vias 710.

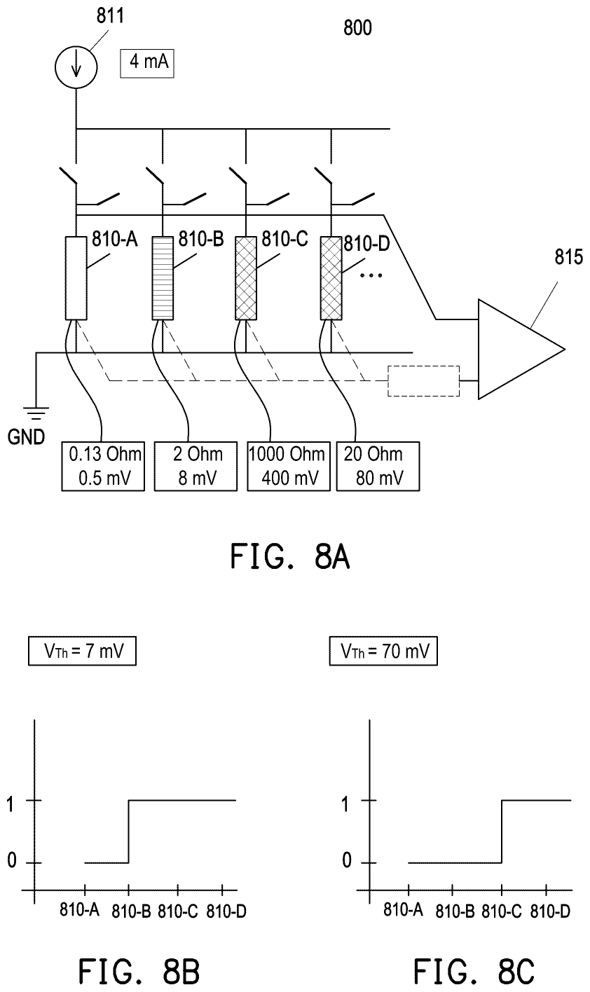

In operation, the ADC 715 may compare a voltage of the first input against the reference voltage 725. The reference voltage may be set so as to identify degraded vias. For example, at high resistances caused by degraded vias, the voltage measured at the first input will be correspondingly high and the comparator will output a signal indicating that the voltage at the first input is higher than reference voltage 725. By comparing the output of the comparator to the pre-determined order in which the plurality of vias are connected, the location of a particular degraded via may be determined. Using a reference voltage as the second input to the ADC may allow for more precise tuning of the sensing window for the circuit, as described in greater detail below with respect to FIGS. 8A-8C.

FIGS. 8A, 8B, and 8C are diagrams showing how a sensing window of a circuit for measuring the resistance of a plurality of vias can be tuned. FIG. 8A is a diagram depicting a circuit for measuring the resistance of a plurality of vias. FIGS. 8B and 8C are diagrams depicting graphs showing an output of the circuit under different operating conditions.

FIG. 8A shows a circuit 800 that may have components similar to those described in examples above. The circuit may be designed to measure the resistance of a plurality of vias including vias 810-A, 810-B, 810-C, and 810-D in order to determine the presence and location of any degraded vias. Circuit 800 may take the form of any of the embodiments described above. For example, FIG. 8 shows dashed lines connecting to the bottom of each via of the plurality of vias. This represents that circuit 800 may have the connection scheme as shown in FIG. 5, FIG. 6, or FIG. 7.

The sensing window of the circuit may be tuned by adjusting the characteristics of the ADC, the value of V_{REF}, and/or the current supplied by the current source. For example, the level of degradation to be screened out can be easily selected by setting these parameters. FIG. 8A shows example values for the supplied current, the voltage across each via of the plurality of vias, and the measured resistance of the vias. FIGS. 8B and 8C show graphs that demonstrate how the tuning of these parameters can change the determination based on the level of resistance sought to be screened.

In an example, current source 811 can supply a constant current of 4 mA. A first via of the plurality of vias 810-A may have a resistance of 0.13 Ohm resulting in a voltage drop of 0.5 mV, a second via of the plurality of vias 810-B may have a resistance of 2 Ohm resulting in a voltage drop of 8 mV, a third via of the plurality of vias 810-C may have a resistance of 1000 Ohm resulting in a voltage drop of 4000 mV, and a fourth via of the plurality of vias may have a resistance of 20 Ohm resulting in a voltage drop of 80 mV.

In an embodiment, the first resistance may be within operating normal conditions and indicate that via 810-A is not degraded. In contrast, the resistances of vias 810-C and 810-D may be above normal operating conditions and indicate that both vias are degraded beyond a tolerable amount. The second via 810-B, however, may be at a level that is acceptable in some circumstances, and unacceptable in others. By tuning the circuit parameters (ADC characteristics, V_{REF}, current supply, as described above), different levels of screening may be achieved such that in some implementations 810-B is flagged as degraded and in others 810-B shows as within normal operating conditions.

FIGS. 8B and 8C show this difference. In FIG. 8B, the parameters of the circuit may be set such that the voltage level that triggers a change of a “0” output to a “1” output from the ADC 815 occurs at 7 mV. This voltage may be considered the threshold voltage (V_{TH}) of the ADC 815. In such an implementation, the ADC 815 triggers a “1” signal when measuring the characteristics of via 810-B, indicating that the via has degraded beyond an acceptable tolerance. In FIG. 8C, the parameters of the circuit may differ, and the threshold voltage of the ADC 815 may be set at 70 mV. In this implementation, the ADC 815 may maintain a “0” signal when measuring the characteristics of 810-B indicating that, based on the needs of the specific design, the via is still operating in an acceptable range.

Like the examples described above, the plurality of vias may be connected and disconnected from a measurement in a pre-determined order such that, by analyzing the output of the ADC 815 it can be determined which specific vias correspond to a “1” output signal and are therefore degraded. By providing a measuring circuit as described in the embodiments above, a defect parasitic resistance of approximately fifty times a nominal parasitic resistance may be detected. This may represent a measurement that is up to twenty times more sensitive than using a circuit that measures RC delay to identify defects.

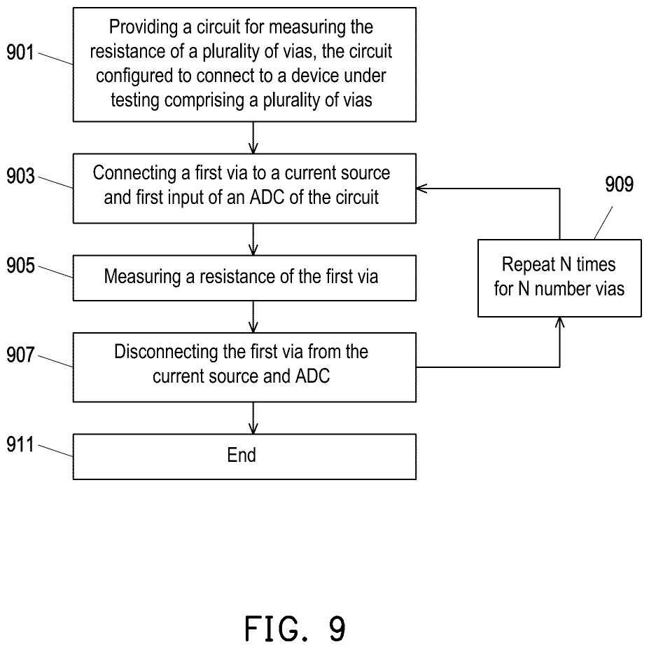

FIG. 9 is a flowchart depicting a method of testing a semiconductor device. The method of testing may use the circuits described above for measuring a resistance across a plurality of vias to determine if any vias of the device are degraded. The method may begin at 901 by receiving a semiconductor device including a circuit for measuring the resistance of a plurality of vias. The semiconductor device may include the plurality of vias extending through a substrate.

The semiconductor device may be similar to that described above with respect to FIG. 3A or 3B, and the plurality of vias may include a plurality of TSVs, a plurality of SPRs, or a combination thereof. The circuit for measuring the resistance of the plurality of vias may be a circuit as described in the embodiments above. For example, the circuit may comprise the circuit of FIG. 4. The circuit may be formed as a part of the semiconductor device and disposed at least partially within a device and routing layer on a top side of the plurality of vias and a backside routing layer on a bottom side of the plurality of vias. In other embodiments, the semiconductor device may be connected to the circuit externally. The device may be tested using a wafer probing method.

At 903, a first via of the plurality of vias is connected to a current source of the circuit and a first input of an ADC of the circuit. As described above, this connection may be enacted by a plurality of switches that are controlled by a digital controller. For example, the plurality of vias may comprise the plurality of vias 410, and digital controller 417 may control the plurality of switches 413 to connect one via at a time to current source 411 and to a first wire 471 that is also connected to a first input of the ADC 415. The plurality of vias may also be connected to a second input of the ADC 415 through a second wire 472. However, as described above with reference to FIG. 7, in other embodiments, the second input of the ADC may be connected to a reference voltage.

At 905 a measurement of the resistance of the first via 410-A may be taken. This measurement may comprise a reading corresponding to an output signal of the ADC 415. In an embodiment ADC 415 measures a voltage across the via using a four-wire sensing scheme, and outputs a signal that indicates whether the measured voltage is above or below a threshold voltage that represents a level of degradation that is not within an acceptable range. Because the current supplied is constant, the measured voltage also corresponds to the resistance of the via. Accordingly, the output signal of the ADC indicates whether the via being measured has a resistance that is above or below an acceptable amount of resistance.

At 907, the first via may be disconnected from the current source and the ADC. In an embodiment, this may also be controlled by signals from the digital controller 417. As indicated at 909, the method may then proceed back to 903 where another via of the plurality of vias is connected to the current source and ADC and its resistance is measured. In the example of FIG. 4, 410-A may be disconnected and 410-B may be connected and measured.

As shown at 909, this process may be repeated any number of times until all vias of the device are measured. In a device having N vias, a number which may be in the hundreds or thousands, the process may be repeated N times. Finally, after the resistance of all vias has been measured, the method may end at 911. A reading of the ADC output may then show a measurement across all vias of the device, and any degraded vias within the device may be located.

Circuits, methods, and systems are described herein. In an example circuit for detecting degradation of a via, a current source configured to supply a constant current is connected to a plurality of conductive vias of a device under testing. A plurality of switches configured to connect the current source to the plurality of vias, and an analog-to-digital-converter (ADC) configured to connect to the plurality of vias by the plurality of switches through a first wire are provided. The plurality of switches are configured to connect one via of the plurality of vias at a time to the current source and the ADC, and the ADC is configured to output a signal that represents the resistance of a via connected to the ADC and the current source.

An example method of testing a plurality of vias includes providing a circuit comprising a current source, a plurality of switches, and an analog-to-digital-converter (ADC). The circuit is connected to a device under testing comprising a plurality of vias. A first via of the plurality of vias is connected to the current source using a first switch of the plurality of switches and a first wire using a second switch of the plurality of switches, wherein the first wire connects to a first input of the ADC. A resistance of the first via is measured using the ADC. The first via is disconnected from the current source and the first wire. A second via of the plurality of vias is connected to the current source using a third switch of the plurality of switches and to the first wire using a fourth switch of the plurality of switches. The resistance of the second via is measured using the ADC.

An example testing system includes a device under testing and a circuit. The device under testing includes a substrate comprising a first surface and a second surface opposite the first surface, a plurality of vias disposed within the substrate and extending between the first surface and the second surface. The device also includes a device and routing layer disposed over the substrate and a backside routing layer disposed below the substrate. The circuit comprises an analog-to-digital converter (ADC) in the device and routing layer and having a first input connected to a first wire, wherein the first wire is configured to be connected to the plurality of vias by a plurality of switches. The circuit also includes at least one second wire in the backside routing layer and connected to at least one via of the plurality of vias on a bottom side of the at least one via. The ADC is configured to output a signal that represents resistance values of the plurality of vias.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

It is claimed:

1. A circuit for detecting via degradation, comprising:
a current source configured to deliver a constant current supply to a plurality of conductive vias of a device under testing;
a plurality of switches configured to connect the current source to the plurality of vias; and
an analog-to-digital converter (ADC) configured to be connected to the plurality of vias by the plurality of switches through a first wire, wherein the first wire is connected to a first input of the ADC,
wherein the plurality of switches are configured to connect one via of the plurality of vias at a time to the current source and to the first wire; and
wherein the ADC is configured to output a signal that represents the resistance of a via connected to the ADC and the current source.

2. The circuit of claim 1, wherein the plurality of vias comprises a plurality of through-silicon-vias (TSVs).

3. The circuit of claim 1, wherein the plurality of vias comprises a plurality of super power rails (SPRs).

4. The circuit of claim 1, wherein the plurality of vias comprises both TSVs and SPRs.

5. The circuit of claim 1, further comprising a plurality of second wires connected to the plurality of vias in a one-to-one correspondence; and
a plurality of return vias in a one-to-one correspondence with the plurality of second wires and the plurality of vias.

6. The circuit of claim 1, further comprising a second wire connected to each of the plurality of vias, wherein the second wire is configured to connect the plurality of vias to a second input of the ADC.

7. The circuit of claim 1, wherein the ADC comprises a second input that is connected to a reference voltage.

8. The circuit of claim 1, wherein the ADC measures a voltage across the via connected to the ADC and the current source, and is configured to output a signal that indicates whether the voltage is above or below a threshold voltage; and
the threshold voltage corresponds to a resistance level of a degraded via.

9. The circuit of claim 1, further comprising a digital controller,
wherein the digital controller is configured to control the plurality of switches to connect the plurality of vias to the current source and the ADC in a pre-determined order.

10. The circuit of claim 1, wherein the ADC comprises a comparator.

11. A method of testing a plurality of vias, comprising:
providing a circuit comprising a current source, a plurality of switches, and an analog-to-digital converter (ADC), wherein the circuit is configured to connect to a device under testing and the device under testing comprises the plurality of vias;
connecting a first via of the plurality of vias to the current source using a first switch of the plurality of switches and to a first wire using a second switch of the plurality of switches, wherein the first wire connects to a first input of the ADC;
measuring a resistance of the first via using the ADC;
disconnecting the first via of the plurality of vias from the current source and the first wire;
connecting a second via of the plurality of vias to the current source using a third switch of the plurality of switches and to the first wire using a fourth switch of the plurality of switches; and
measuring a resistance of the second via using the ADC.

12. The method of claim 11, wherein the plurality of vias comprises N number of vias; and
the method comprises measuring the resistance of N number of vias.

13. The method of claim 11, wherein the connecting the first via, disconnecting the first via, connecting the second via, and disconnecting the second via, is controlled by a digital controller.

14. The method of claim 11, wherein the plurality of vias are configured to connect to a second input of the ADC through a plurality of second wires having a one-to-one correspondence with the plurality of vias.

15. The method of claim 11, wherein each of the plurality of vias are connected to a second wire that is configured to connect the plurality of vias to a second input of the ADC.

16. The method of claim 11, wherein the ADC comprises a second input that is connected to a reference voltage; and
the measuring a resistance of the first via and measuring a resistance of the second via comprises comparing a voltage measured at the first input to the reference voltage.

17. A testing system, comprising:
a device under testing; and
a circuit;
the device under testing comprising:
a substrate comprising a first surface and a second surface opposite the first surface;
a plurality of vias disposed within the substrate and extending between the first surface and the second surface;
a device and routing layer disposed over the substrate; and
a backside routing layer disposed below the substrate;
the circuit comprising:
an analog-to-digital converter (ADC) disposed in the device and routing layer and having a first input connected to a first wire, wherein the first wire is configured to be connected to the plurality of vias by a plurality of switches; and
at least one second wire disposed in the backside routing layer and connected to at least one via of the plurality of vias on a bottom side of the at least one via,
wherein the ADC is configured to output a signal that represents resistance values of the plurality of vias.

18. The system of claim 17, wherein the circuit further comprises a current source disposed in the device and routing layer and configured to supply a constant current.

19. The system claim 17, wherein the at least one second wire comprises a plurality of second wires having a one-to-one correspondence with the plurality of vias.

20. The system claim 17, wherein the at least one second wire is connected to each of the plurality of vias and is further connected to a second input of the ADC.
